(19) United States
(12) Patent Application Publication
(10) Pub. No.: US 2026/0054344 A1
(43) Pub. Date: Feb. 26, 2026

(54) GRINDING APPARATUS, GRINDING METHOD, AND DIAMOND SUBSTRATE GENERATION METHOD

(71) Applicant: DISCO CORPORATION, Tokyo (JP)

(72) Inventors: Masahiro Kobayashi, Tokyo (JP); Yusuke Hori, Tokyo (JP); Yuya Seto, Tokyo (JP)

(21) Appl. No.: 19/291,997

(22) Filed: Aug. 6, 2025

(30) Foreign Application Priority Data
Aug. 23, 2024 (JP) 2024-141984
Apr. 25, 2025 (JP) 2025-073173

(51) Int. Cl. B24B 7/22; H01L 21/02

(52) U.S. Cl. CPC B24B 7/228; H01L 21/02013

(57) ABSTRACT

A grinding apparatus capable of easily processing an end surface of a diamond substrate into a planar surface, where the grinding apparatus includes a holding unit for holding the diamond substrate, a grinding unit including a grinding tool for grinding the end surface of the diamond substrate held by the holding unit, and a grinding feed unit for grinding-feeding the grinding unit in a direction that brings the grinding unit closer to and away from the end surface of the diamond substrate held by the holding unit. The grinding tool has a base and a grinding blade mounted on the base. The grinding blade is made of iron and acts on the end surface of the diamond substrate to cause a reaction between the iron and carbon of diamond and generate a compound containing austenite, thereby grinding the end surface of the diamond substrate.

### BACKGROUND

### 1. Technical Field

The present disclosure relates to a grinding apparatus and a grinding method each for grinding an end surface of a diamond substrate and to a diamond substrate generation method for generating a diamond substrate from a diamond ingot.

### 2. Description of the Related Art

A plurality of devices, such as ICs or LSIs, are formed in the form of a wafer by stacking functional layers on an upper surface of a semiconductor substrate made of Si or the like, demarcating the semiconductor substrate into sections with division lines, and then dividing the semiconductor substrate into individual device chips with a dicing apparatus or a laser processing apparatus. Each of the device chips resulting from the division is used in an electrical device such as a mobile phone or a personal computer.

In recent years, diamond having excellent dielectric strength, thermal conductivity, and physical properties has been attracted attention as a semiconductor substrate (see, e.g., JP 2008-78611 A and JP 2015-57824 A). Accordingly, the present applicant has proposed a technology of efficiently generating diamond substrates from a diamond ingot (see, e.g., JP 2020-50563 A).

### SUMMARY

However, a peel-off surface of a diamond substrate peeled from an ingot has sharp undulations like those of a file, hence there is a problem in that it is difficult to process the peel-off surface into a planar surface.

A task of the present disclosure is to provide a grinding apparatus and a grinding method which allow an end surface of a diamond substrate to be easily processed into a planar surface and a diamond substrate generation method that allows the diamond substrate having the planar end surface to be easily generated.

According to the present disclosure, the following grinding apparatus that solves the problem described above is provided. In other words, there is provided “A grinding apparatus for grinding an end surface of a diamond substrate, the grinding apparatus including: a holding unit for holding the diamond substrate; a grinding unit including a grinding tool for grinding the end surface of the diamond substrate held by the holding unit; and a grinding feed unit for grinding-feeding the grinding unit in a direction that brings the grinding unit closer to and away from the end surface of the diamond substrate held by the holding unit, the grinding tool having a base and a grinding blade mounted on the base, the grinding blade being made of iron and acting on the end surface of the diamond substrate to cause a reaction between the iron and carbon of diamond and generate a compound containing austenite, thereby grinding the end surface of the diamond substrate”.

According to the present disclosure, the following grinding method that solves the problem described above is provided. In other words, the grinding method is “A grinding method for grinding an end surface of a diamond substrate, the grinding method including: holding the diamond substrate by a holding unit; and grinding the end surface of the diamond substrate held by the holding unit with a grinding unit including a grinding tool, the grinding tool including a base and a grinding blade mounted on the base, the grinding blade being made of iron and acting on the end surface of the diamond substrate to cause a reaction between the iron and carbon of diamond and generate a compound containing austenite, thereby grinding the end surface of the diamond substrate”.

Preferably, the iron is pure iron. It is desirable that the diamond substrate is generated from a diamond ingot having a crystal plane (001) as an end surface, a focal point of a laser beam having a wavelength transparent to the diamond is positioned at a depth equivalent to a thickness of the diamond substrate to be generated from the end surface of the diamond ingot, the laser beam is applied to the diamond ingot, while the diamond ingot and the focal point are moved relative to each other in a [110] direction perpendicular to the crystal plane (110), to form a peel-off band, the diamond ingot and the focal point are index-fed relative to each other in a direction parallel to the crystal plane (001) and perpendicular to the [110] direction, the formation of the peel-off band and the index-feeding are repeated to form a peel-off layer parallel to the crystal plane (001) inside the diamond ingot, and a peel-off surface of the diamond substrate peeled from the diamond ingot by using the peel-off layer as an interface is ground.

According to the present disclosure, the following diamond substrate generation method that solves the problem described above is provided. In other words, there is provided “A diamond substrate generation method for generating a diamond substrate from a diamond ingot, the diamond substrate generation method including: positioning a focal point of a laser beam having a wavelength transparent to diamond at a depth equivalent to a thickness of the diamond substrate to be generated from an end surface of the diamond ingot; applying a laser beam to the diamond ingot, while moving the diamond ingot and the focal point relative to each other, to form a peel-off layer; peeling the diamond substrate from the diamond ingot by using the peel-off layer as an interface; and grinding a peel-off surface of the diamond substrate with a grinding blade made of iron”.

A grinding apparatus of the present disclosure is a grinding apparatus for grinding an end surface of a diamond substrate, the grinding apparatus including: a holding unit for holding the diamond substrate; a grinding unit including a grinding tool for grinding the end surface of the diamond substrate held by the holding unit; and a grinding feed unit for grinding-feeding the grinding unit in a direction that brings the grinding unit closer to and away from the end surface of the diamond substrate held by the holding unit, the grinding tool having a base and a grinding blade mounted on the base, the grinding blade being made of iron and acting on the end surface of the diamond substrate to cause a reaction between the iron and carbon of diamond, generate a compound containing austenite, and thereby grind the end surface of the diamond substrate, and therefore it is possible to easily process the end surface of the diamond substrate into a planar surface.

A grinding method of the present disclosure is a grinding method for grinding an end surface of a diamond substrate, the grinding method including: holding the diamond substrate by a holding unit; and grinding the end surface of the diamond substrate held by the holding unit with a grinding unit including a grinding tool, the grinding tool including a base and a grinding blade mounted on the base, the grinding blade being made of iron and acting on the end surface of the diamond substrate to cause a reaction between the iron and carbon of diamond, generate a compound containing austenite, and thereby grind the end surface of the diamond substrate, and therefore it is possible to easily process the end surface of the diamond substrate into a planar surface.

A diamond substrate generation method of the present disclosure is a diamond substrate generation method for generating a diamond substrate from a diamond ingot, the diamond substrate generation method including: positioning a focal point of a laser beam with a wavelength transparent to diamond at a depth equivalent to a thickness of the diamond substrate to be generated from an end surface of the diamond ingot; applying a laser beam to the diamond ingot, while moving the diamond ingot and the focal point relative to each other, to form a peel-off layer; peeling the diamond substrate from the diamond ingot by using the peel-off layer as an interface; and grinding a peel-off surface of the diamond substrate with a grinding blade made of iron, and therefore it is possible to easily generate the diamond substrate with the planar end surface.

### BRIEF DESCRIPTION OF THE DRAWINGS

FIG. 1 is a perspective view of a grinding apparatus according to the present disclosure;

FIG. 2 is a perspective view of a diamond substrate and a base substrate;

FIG. 3 is a schematic diagram illustrating holding the diamond substrate;

FIG. 4 is a schematic diagram illustrating grinding an end surface of the diamond substrate;

FIG. 5 is a perspective view of the ground diamond substrate;

FIG. 6 is a schematic diagram illustrating another mode of the grinding;

FIG. 7 is a perspective view illustrating another mode of a grinding unit;

FIG. 8A illustrates a planar image of the diamond substrate ground by using a grinding blade of the grinding unit illustrated in FIG. 7 and FIG. 8B illustrates a cross-sectional image of the diamond substrate ground by using the grinding blade of the grinding unit illustrated in FIG. 7;

FIG. 9A illustrates a planar image of the diamond substrate ground in the mode illustrated in FIG. 4 and FIG. 9B illustrates a cross-sectional image of the diamond substrate ground in the mode illustrated in FIG. 4;

FIG. 10 is a perspective view of a diamond ingot;

FIG. 11 is a schematic diagram illustrating a state where peel-off bands are formed in the diamond ingot illustrated in FIGS. 8A and 8B;

FIG. 12 is a schematic diagram of a focal point of a laser beam illustrated in FIGS. 9A and 9B;

FIG. 13 is a schematic diagram of the diamond ingot in which a plurality of the peel-off bands are formed; and

FIG. 14A is a perspective view illustrating a state where the diamond ingot is positioned below a peeling apparatus, FIG. 14B is a schematic diagram illustrating peeling, and FIG. 14C is a perspective view of the diamond ingot and the diamond substrate.

### DETAILED DESCRIPTION

Referring to the drawings, a description will be given of embodiments of a grinding apparatus according to the present disclosure.

### Grinding Apparatus 2

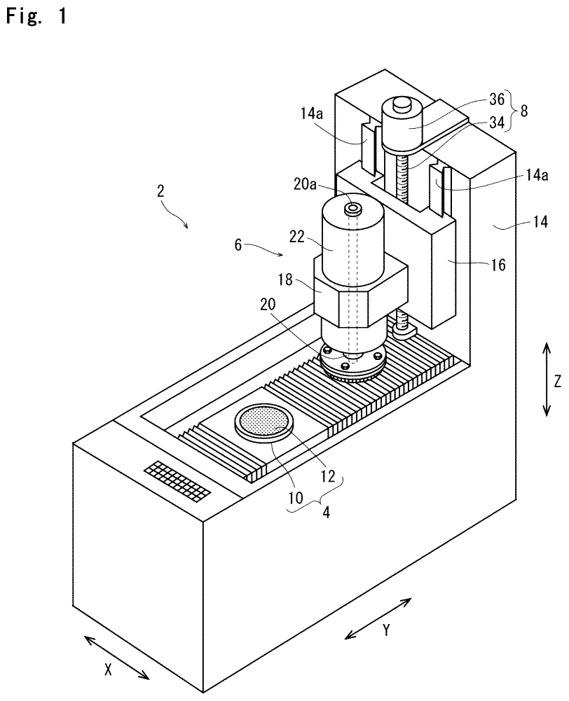

As illustrated in FIG. 1, a grinding apparatus 2 includes a holding unit 4 for holding a diamond substrate, a grinding unit 6 including a grinding tool for grinding an end surface of the diamond substrate held by the holding unit 4, and a grinding feed unit 8 for grinding-feeding the grinding unit 6 in a direction that brings the grinding unit 6 closer to and away from the end surface of the diamond substrate held by the holding unit 4.

### Holding Unit 4 of Grinding Apparatus 2

The holding unit 4 includes a chuck table 10 for suction-holding the diamond substrate. On an upper end of the chuck table 10, a circular suction chuck 12 is disposed. The suction chuck 12 is formed of a porous member such as a porous ceramic. In addition, the suction chuck 12 is connected to a suction pump (not shown). The holding unit 4 generates a suction force on an upper surface of the suction chuck 12 to suction-hold the diamond substrate placed on the upper surface of the suction chuck 12. Meanwhile, the chuck table 10 is moved in a Y-axis direction by a Y-axis feeding unit (may be of a ball screw type) not shown, while being rotated around a Z-axis direction serving as an axis center by a motor not shown. Note that the Y-axis direction is a direction indicated by an arrow Y in FIG. 1, while the Z-axis direction is a vertical direction indicated by an arrow Z in FIG. 1, which is a direction perpendicular to the Y-axis direction. Meanwhile, an X-axis direction indicated by an arrow X in FIG. 1 is a direction perpendicular to each of the Y-axis direction and the Z-axis direction, while an XY-plane defined by the X-axis direction and the Y-axis direction is substantially horizontal.

### Grinding Unit 6 of Grinding Apparatus 2

The grinding unit 6 includes a Z-axis movable plate 16 supported by a support wall 14 provided at an end portion (depth-side end portion in FIG. 1) of the grinding apparatus 2 to be movable in the Z-axis direction, a protruding member 18 protruding from the Z-axis movable plate 16, a spindle 20 supported by the protruding member 18 to be rotatable around an axial line extending in the Z-axis direction, and a spindle motor 22 for rotating the spindle 20. The spindle 20 extends through the spindle motor 22. The spindle 20 is formed hollow and, to an upper end 20a of the spindle 20, grinding water is supplied from a grinding water supply unit (not shown). The grinding water supplied to the spindle 20 is supplied to a wafer and to a grinding blade 32 described below during grinding.

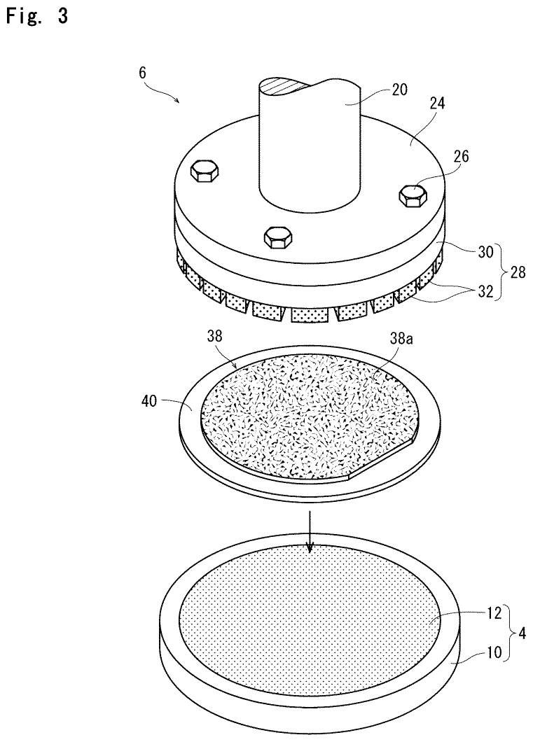

Referring to FIG. 3, the description will be continued. To a lower end of the spindle 20, a disc-shaped mounter 24 is fixed and, to a lower surface of the mounter 24, a grinding tool 28 is fastened with bolts 26. The grinding tool 28 has an annular base 30 and a grinding blade 32 mounted on the base 30. The grinding blade 32 in the present embodiment is provided in an annular shape (having a diameter of, e.g., about 20 cm) on a lower surface of the base 30. The grinding blade 32 is made of iron. The iron forming the grinding blade 32 is preferably pure iron. The pure iron in the present specification has a Fe (iron) content of not less than 99 mass %.

### Grinding Feed Unit 8 of Grinding Apparatus 2

As illustrated in FIG. 1, the grinding feed unit 8 has a ball screw 34 extending in the Z-axis direction along one surface of the support wall 14 and a motor 36 for rotating the ball screw 34. The ball screw 34 has a nut portion (not shown) connected to the Z-axis movable plate 16. The grinding feed unit 8 uses the ball screw 34 to convert rotary motion of the motor 36 to linear motion and transmit the linear motion to the Z-axis movable plate 16, and grinding-feeds the grinding unit 6 in the Z-axis direction along a guide rail 14a additionally provided on the one surface of the support wall 14.

### Grinding Method

Next, a description will be given of embodiments of a grinding method according to the present disclosure. A description is given herein of a method of grinding the end surface of the diamond substrate by using the grinding apparatus 2 described above.

### Base Substrate Mounting

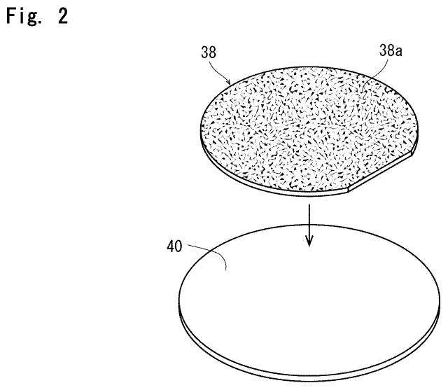

In the present embodiment, first, as illustrated in FIG. 2, base substrate mounting is performed to mount a base substrate 40 on a diamond substrate 38 via an appropriate adhesive. The base substrate 40 may be made appropriately of, e.g., glass, and can be formed in a disc shape having a diameter of not less than a diameter of the diamond substrate 38.

### Holding Diamond Substrate

After the base substrate mounting is performed, the diamond substrate 38 is held by the holding unit 4. For the holding, the Y-axis feeding unit is actuated first to position the chuck table 10 at a mounting/demounting position illustrated in FIG. 1. Then, as illustrated in FIG. 3, an end surface 38a (uneven surface to be ground) of the diamond substrate 38 is faced upward, and the diamond substrate 38 with the base substrate 40 mounted thereon is placed on an upper surface of the chuck table 10. Then, the suction pump is actuated to generate a suction force on an upper surface of the suction chuck 12 and cause the diamond substrate 38 to be suction-held on the chuck table 10 of the holding unit 4.

### Grinding

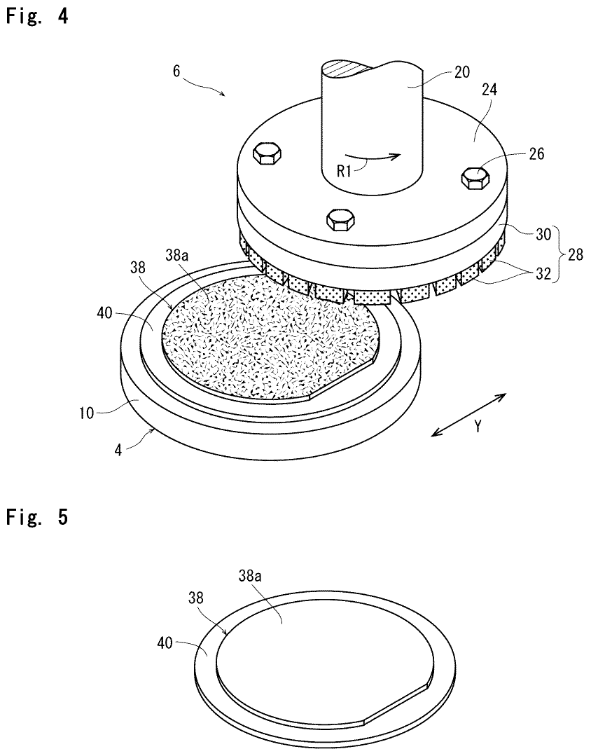

After the holding is performed, the end surface 38a of the diamond substrate 38 held by the holding unit 4 is ground with the grinding unit 6 including the grinding tool 28 for grinding the end surface 38a. For the grinding, the Y-axis feeding unit is actuated first to position the chuck table 10 below the grinding unit 6. Then, the spindle 20 is rotated at a predetermined rotation speed (e.g., 10000 rpm) in a direction indicated by an arrow R1 in FIG. 4. The chuck table 10 is also reciprocated in the Y-axis direction at a predetermined feeding speed (e.g., 10 mm/s). Then, the spindle 20 is lowered with the grinding feed unit 8 to bring the grinding blade 32 into contact with the end surface 38a of the diamond substrate 38, while the grinding water is supplied to a portion of the end surface 38a with which the grinding blade 32 is brought into contact. As a result, the grinding blade 32 made of iron acts on the end surface 38a of the diamond substrate 38 to cause a reaction between the iron and carbon of diamond, generate a compound containing austenite, and thereby grind the end surface 38a of the diamond substrate 38. Such grinding is repeated, while the spindle 20 is downwardly grinding-fed in a predetermined amount (e.g., 0.1 μm). Consequently, as illustrated in FIG. 5, it is possible to process the end surface 38a of the diamond substrate 38 into a planar surface.

The grinding is not limited to the mode illustrated in FIG. 4, and may also be in another mode. As described above, in the grinding, the iron and the carbon of the diamond react with each other to generate the compound containing the austenite and thereby grind the end surface 38a of the diamond substrate 38. In other words, during the grinding, it is important to increase a relative speed between the diamond substrate 38 and the grinding blade 32 to such a degree as to produce frictional heat that generates the compound containing the austenite. Accordingly, as long as a relative speed sufficient to produce the frictional heat that generates the compound containing the austenite can be achieved, the grinding is not limited to the mode illustrated in FIG. 4, and may also be in another mode.

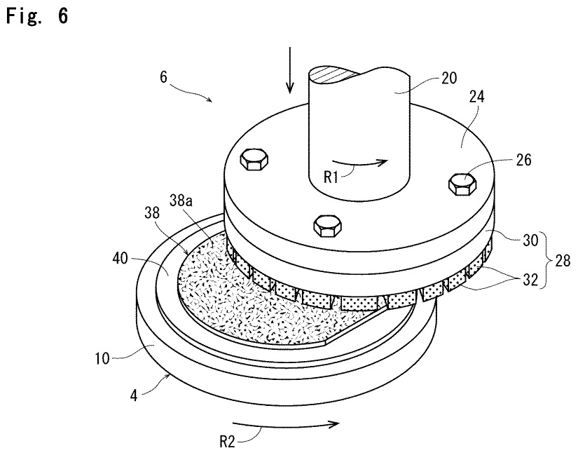

For example, as illustrated in FIG. 6, in the grinding, it may also be possible that the spindle 20 is rotated at a predetermined rotation speed (e.g., 10000 rpm) in the direction indicated by the arrow R1, while the chuck table 10 is rotated at a predetermined rotation speed (e.g., 500 rpm) as indicated by an arrow R2. Then, the spindle 20 is lowered with the grinding feed unit 8 to bring the grinding blade 32 into contact with the end surface 38a of the diamond substrate 38, while the grinding water is supplied to the portion of the end surface 38a with which the grinding blade 32 is to be brought into contact. Then, the spindle 20 is lowered at a predetermined grinding feed speed (e.g., 0.01 μm/s). Even when the grinding is performed in such a mode, the grinding blade 32 made of iron acts on the end surface 38a of the diamond substrate 38 to cause the reaction between the iron and the carbon of the diamond, generate the compound containing the austenite, and thereby grind the end surface 38a of the diamond substrate 38. Therefore, it is possible to process the end surface 38a of the diamond substrate 38 into a planar surface.

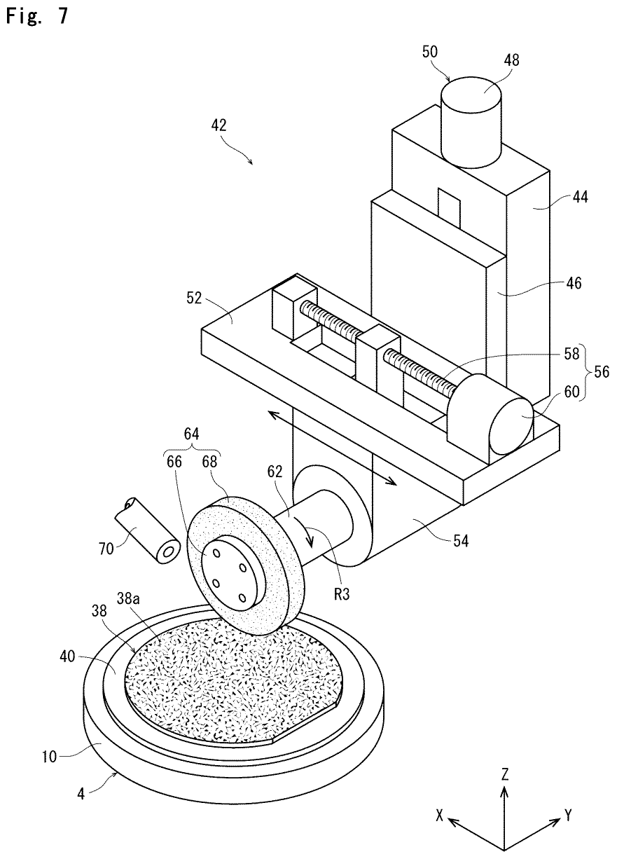

Alternatively, the grinding may also be performed using a grinding unit (e.g., a grinding unit 42 illustrated in FIG. 7) other than the grinding unit 6 illustrated in FIG. 4. The grinding unit 42 illustrated in FIG. 7 includes a Z-axis guide member 44 and a Z-axis movable plate 46 supported by the Z-axis guide member 44 to be movable in the Z-axis direction. The Z-axis movable plate 46 is grinding-fed in the Z-axis direction by a grinding feed unit 50 having a ball screw (not shown) extending in the Z-axis direction and a motor 48 for rotating the ball screw.

The grinding unit 42 illustrated in FIG. 7 further includes an X-axis guide member 52 fixed to the Z-axis movable plate 46, an X-axis movable member 54 supported by the X-axis guide member 52 to be movable in the X-axis direction, and an X-axis feeding unit 56 for moving the X-axis movable member 54 in the X-axis direction. The X-axis feeding unit 56 has a ball screw 58 connected to the X-axis movable member 54 to extend in the X-axis direction and a motor 60 for rotating the ball screw 58. On the X-axis movable member 54, a spindle 62 is rotatably supported around the Y-axis direction serving as an axis center, and a motor (not shown) for rotating the spindle 62 is provided. To a leading end of the spindle 62, a grinding tool 64 is attached. The grinding tool 64 has a disc-shaped base 66 and an annular or disc-shaped grinding blade 68 disposed on the base 66. The grinding blade 68 is made of iron. The iron forming the grinding blade 68 is preferably pure iron. Note that a diameter of the grinding blade 68 may appropriately be about 5 cm, while a thickness of the grinding blade 68 may appropriately be about 5 mm to 10 mm.

When the grinding is to be performed using the grinding unit 42 illustrated in FIG. 7, first, the spindle 62 is rotated at a predetermined rotation speed (e.g., 20000 rpm) in a direction indicated by an arrow R3. In addition, the X-axis movable member 54 is reciprocated at a predetermined feeding speed (e.g., 10 mm/s) in the X-axis direction. Then, the spindle 62 is lowered with the grinding feed unit 50 to bring the grinding blade 68 into contact with the end surface 38a of the diamond substrate 38, while grinding water is supplied from a grinding water supply nozzle 70 to the portion of the end surface 38a with which the grinding blade 68 is brought into contact. As a result, the grinding blade 68 made of iron acts on the end surface 38a of the diamond substrate 38 to cause a reaction between the iron and the carbon of the diamond, generate the compound containing the austenite, and thereby grind the end surface 38a of the diamond substrate 38. In such grinding, the entire end surface 38a of the diamond substrate 38 is ground to be processed into the planar surface, while index-feeding of the chuck table 10 in the Y-axis direction and downward grinding-feeding of the spindle 62 is repeated as appropriate.

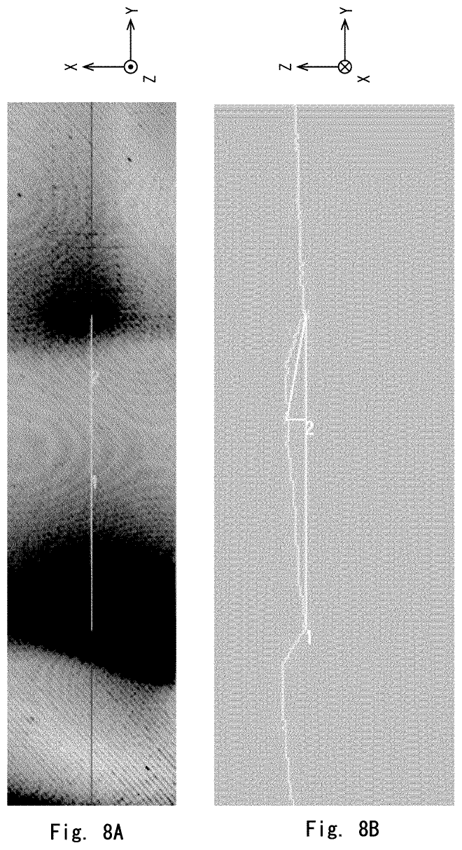

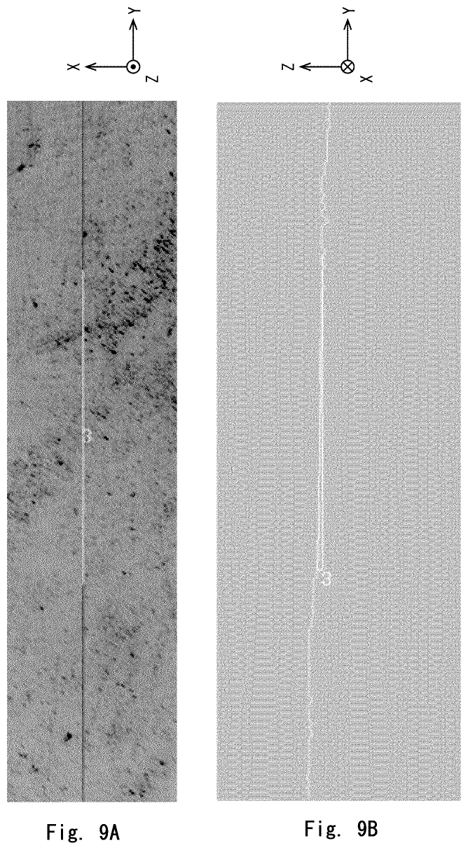

After the end surface 38a of the diamond substrate 38 is ground using the grinding unit 42 illustrated in FIG. 7, the end surface 38a of the diamond substrate 38 may also be further ground in the mode illustrated in FIG. 4 or FIG. 6. This can reduce surface roughness of the end surface 38a of the diamond substrate 38. When the diamond substrate 38 is ground using the grinding blade 68 of the grinding unit 42 illustrated in FIG. 7, unevenness specific to the grinding blade 68 may appear at the end surface 38a of the diamond substrate 38. Meanwhile, when the diamond substrate 38 is ground in the foregoing mode illustrated in FIG. 4 or FIG. 6, there is no appearance of the unevenness specific to the grinding blade 32 at the end surface 38a of the diamond substrate 38. By way of example, as a result of grinding the diamond substrate by using the grinding blade 68 of the grinding unit 42 illustrated in FIG. 7, an unevenness level difference at the end surface of the diamond substrate was 23.6 μm (a result of measuring a level difference at the end surface of the diamond substrate along the Y-direction. See FIGS. 8A and 8B) and, when the diamond substrate is subsequently ground in the foregoing mode illustrated in FIG. 4, the unevenness level difference at the end surface of the diamond substrate was 5.91 μm (a result of measuring the level difference at the end surface of the diamond substrate along the Y-direction. See FIGS. 9A and 9B). Note that the grinding blade when the end surface 38a of the diamond substrate 38 is ground using the grinding unit 42 illustrated in FIG. 7 and then the end surface 38a of the diamond substrate 38 is further ground in the mode illustrated in FIG. 4 or FIG. 6 may also the grinding blade 32 made of iron, since an amount of grinding in the mode illustrated in FIG. 4 or FIG. 6 is small, or may also be a grinding wheel containing abrasive grains made of diamond, CBN (Cubic Boron Nitride), or the like and a bond material such as metal bond, resin bond, or vitrified bond.

As described heretofore, in the present embodiment, the grinding blade 32 (68) acts on the end surface 38a of the diamond substrate 38 to cause the reaction between the iron and the carbon of the diamond, generate the compound containing the austenite, and thereby grind the end surface 38a of the diamond substrate 38. Therefore, it is possible to easily process the end surface 38a of the diamond substrate 38 into a planar surface.

Note that the grinding blades 32 and 68 made of iron may also be those in which diamond abrasive grains are mixed. When the grinding blade in which the diamond abrasive grains are mixed in the iron is used, the surface roughness of the end surface of the diamond substrate after grinding can further be reduced. By way of example, in a case where the grinding blade 68 made of pure iron was used when the end surface of the diamond substrate was ground using the grinding unit 42 illustrated in FIG. 7, a surface roughness Ra (arithmetic average roughness) at the end surface of the diamond substrate was 26 nm. Meanwhile, in a case where a grinding blade in which the diamond abrasive grains are mixed in the iron was used as the grinding blade 68 when the end surface of the diamond substrate was ground using the grinding unit 42 illustrated in FIG. 7, the surface roughness Ra (arithmetic average roughness) at the end surface of the diamond substrate was 6 nm. A degree of concentration of the diamond abrasive grains in this case is 50. The surface roughness Ra was measured along the X-direction in which the grinding blade 68 was reciprocated.

Next, a description will be given of a method of generating the diamond substrate 38 to be ground using the grinding apparatus 2 and the grinding method each exactly as described above.

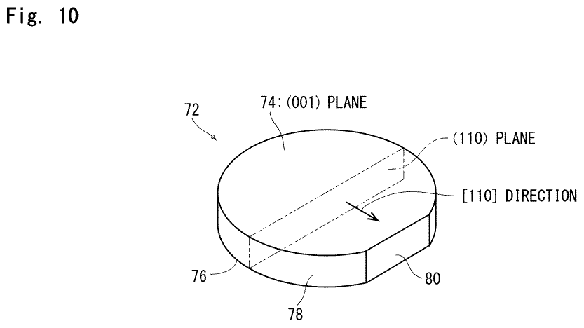

The diamond substrate 38 can be generated from a diamond ingot 72 (see FIG. 10) having a crystal plane (001) as an end surface thereof. The diamond ingot 72 has a circular first end surface 74 having the crystal plane (001) as a planar surface, a circular second end surface 76 opposite to the first end surface 74, and a circumferential surface 78 located between the first end surface 74 and the second end surface 76. The circumferential surface 78 of the diamond ingot 72 is formed with a rectangular orientation flat 80 parallel to a crystal plane (110). In addition, in FIG. 10, a [110] direction perpendicular to the crystal plane (110) is indicated by an arrow.

When the diamond substrate 38 is to be generated from the diamond ingot 72, first, focal point positioning is performed to position a focal point of a laser beam with a wavelength transparent to diamond at a depth equivalent to a thickness of the diamond substrate 38 to be generated from the planar surface.

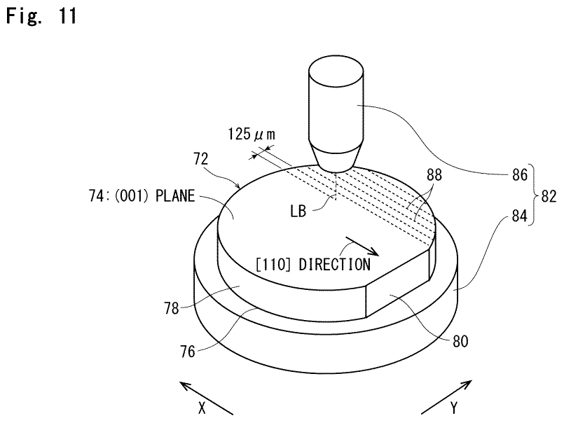

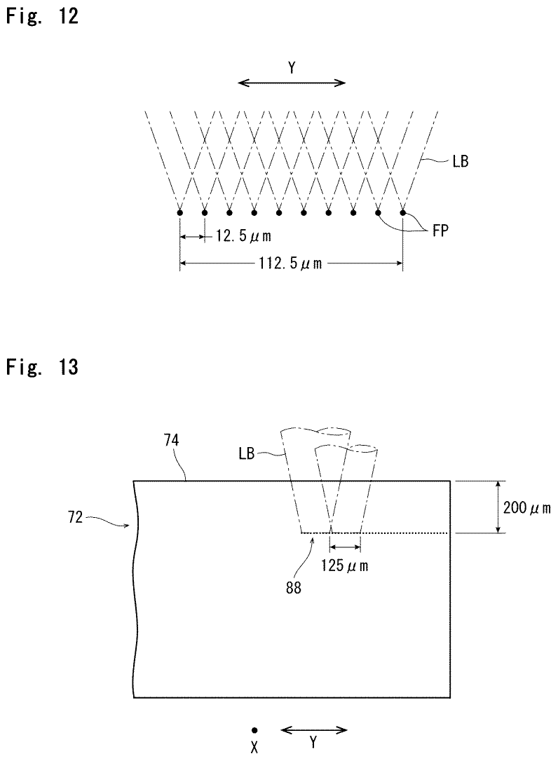

The focal point positioning can be performed using, e.g., a laser processing apparatus 82 illustrated in, e.g., FIG. 11. The laser processing apparatus 82 includes a holding table 84 for holding the diamond ingot 72 and a concentrator 86 for applying a pulse laser beam LB with a wavelength transparent to the diamond to the diamond ingot 72 held by the holding table 84. The holding table 84 is configured to be rotatable around a vertically extending axial line, and is also configured to be movable in each of the X-axis direction indicated by an arrow X in FIG. 11 and the Y-axis direction (direction indicated by an arrow Y in FIG. 11) perpendicular to the X-axis direction. In addition, the holding table 84 is configured to be movable from a region to be processed by the laser processing apparatus 82 to a peeling apparatus 92 described later. Note that a plane defined by the X-axis direction and the Y-axis direction is substantially horizontal.

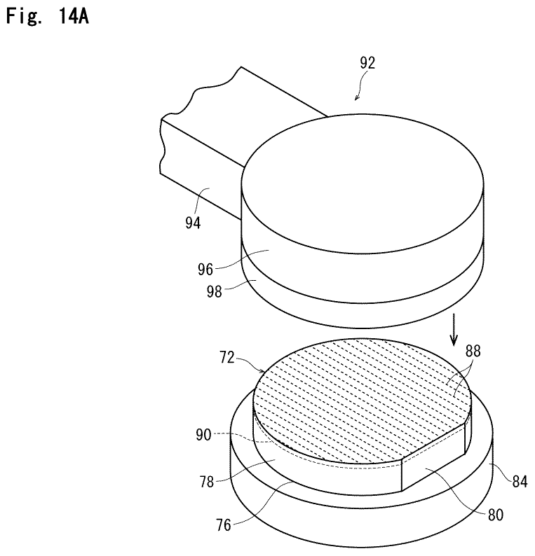

For the focal point positioning, first, the diamond ingot 72 is fixed to an upper surface of the holding table 84 via an appropriate adhesive (e.g., an epoxy-resin-series adhesive). Alternatively, when the upper surface of the holding table 84 is formed with a plurality of suction holes, it may also be possible to generate a suction force at the upper surface of the holding table 84 and suction-hold the diamond ingot 72. Then, using an image capturing unit (not shown) of the laser processing apparatus 82, an image of the diamond ingot 72 is captured from thereabove. Then, on the basis of the image of the diamond ingot 72 captured with the image capturing unit, the holding table 84 is rotated and moved to adjust an orientation of the diamond ingot 72 to a predetermined direction, while adjusting respective positions of the diamond ingot 72 and the concentrator 86 in the XY-plane. When the orientation of the diamond ingot 72 is to be adjusted to the predetermined direction, as illustrated in FIG. 11, the orientation flat 80 is aligned in the Y-axis direction to align the [110] direction perpendicular to the crystal plane (110) in the X-axis direction. Then, using a focal point position adjustment unit (not shown) of the laser processing apparatus 82, the concentrator 86 is moved upward or downward to shift a position of a focal point FP of the pulse laser beam LB with the wavelength transparent to the diamond from the planar first end surface 74 to the depth (e.g., 200 μm) equivalent to the thickness of the diamond substrate 38 to be generated. As illustrated in FIG. 12, it is preferable to branch the laser beam LB and position a plurality of (e.g., ten) focal points FP at intervals in the Y-axis direction.

After the focal point positioning is performed, peel-off band forming is performed to form peel-off bands by applying the laser beam LB to the diamond ingot 72, while moving the diamond ingot 72 and the focal point FP relative to each other in the [110] direction perpendicular to the crystal plane (110).

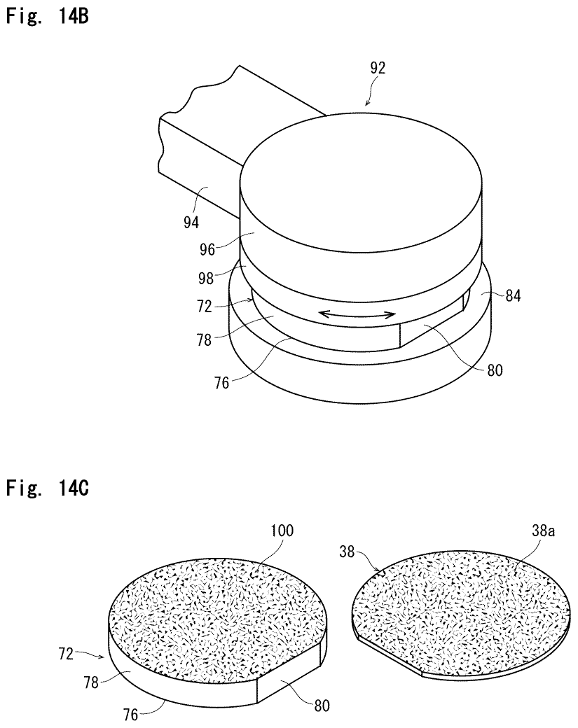

For the peel-off band forming, while the holding table 84 and the focal point FP are moved relative to each other at a predetermined feeding speed in the X-axis direction aligned in the [110] direction perpendicular to the crystal plane (110), the pulse laser beam LB with the wavelength transparent to the diamond is applied from the concentrator 86 to the diamond ingot 72. As a result, the application of the pulse laser beam LB destroys a crystal structure, since peel-off bands 88 are formed along the [110] direction due to isotropic extension of a crack from a portion where the crystal structure was destroyed. In the present embodiment, as illustrated in FIG. 12 and FIG. 13, the plurality of focal points FP are positioned, and therefore it is possible to efficiently form the peel-off bands. Then, index-feeding is performed to index-feed the diamond ingot 72 and the focal point FP relative to each other in a direction parallel to the crystal plane (001) and perpendicular to the [110] direction. Then, the peel-off band forming and the index-feeding are repetitively performed to form a peel-off layer 90 (see FIGS. 14A to 14C) parallel to the crystal plane (001) inside the diamond ingot 72.

The peel-off layer forming and the index-feeding each described above can be performed under, e.g., the following conditions. Note that the number of paths shown below is the number of times the pulse laser beam LB is applied to the same portion of the diamond ingot 72.
Wavelength of Pulse Laser Beam: 1064 nm
Average Output: 0.8 W
Repetitive Frequency: 50 kHz
Feeding Speed: 200 mm/s
Number of Paths: 2 times
Number of Focal Points: 10
Intervals between Focal Points: 12.5 μm
Amount of Index-feeding: 125 μm

After the peel-off layer forming is performed, peeling is performed to peel the diamond substrate 38 from the diamond ingot 72 by using the peel-off layer 90 as an interface. The peeling can be performed by using the peeling apparatus 92 illustrated in FIGS. 14A to 14C. The peeling apparatus 92 includes a substantially horizontally extending arm 94 and a motor 96 additionally provided on a leading end of the arm 94. To a lower surface of the motor 96, a disc-shaped suction piece 98 is connected to be rotatable around a vertically extending axial line. The suction piece 98 is configured to suction the workpiece at a lower surface thereof. In addition, an ultrasonic vibration application unit (not shown) for applying ultrasonic vibration to the lower surface of the suction piece 98 is embedded in the suction piece 98.

Referring to FIGS. 14A to 14C, the description will be continued. For the peeling, first, the holding table 84 holding the diamond ingot 72 is moved to a position under the suction piece 98 of the peeling apparatus 92. Then, the arm 94 is lowered to allow the lower surface of the suction piece 98 to suction the first end surface 74 (end surface closer to the peel-off layer 90) of the diamond ingot 72, as illustrated in FIG. 14B. Then, the ultrasonic vibration application unit is actuated to apply the ultrasonic vibration to the lower surface of the suction piece 98, while causing the motor 96 to rotate the suction piece 98. Thus, as illustrated in FIG. 14C, the diamond substrate 38 can be peeled from the diamond ingot 72 by using the peel-off layer 90 as the interface. Then, the peel-off surface 38a of the diamond substrate 38 is ground using the grinding apparatus 2 and the grinding method each described above.

Note that the diamond substrate generation method is not limited to the embodiment described above, and can be changed as appropriate. For example, for the peel-off band forming described above, the laser beam LB is applied to the diamond ingot 72, while the diamond ingot 72 and the focal point FP are moved relative to each other in the [110] direction perpendicular to the crystal plane (110), but the direction of the relative movement of the diamond ingot 72 and the focal point FP when the laser beam LB is applied need not be the [110] direction perpendicular to the crystal plane (110). In addition, a direction in which the diamond ingot 72 and the focal point FP are index-fed relative to each other in the index-feeding need not be the direction parallel to the crystal plane (001) and perpendicular to the [110] direction. Moreover, the diamond ingot is not limited to the diamond ingot not having the crystal plane (001) as the end surface, and may also be a diamond ingot having a plane other than the crystal plane (001) as the end surface.

### REFERENCE SIGNS LIST

2 Grinding apparatus
4 Holding unit
6 Grinding unit
8 Grinding feed unit
28 Grinding tool
30 Base
32 Grinding blade
38 Diamond substrate
38a End surface of diamond substrate
72 Diamond ingot
88 Peel-off band
90 Peel-off layer

What is claimed is:

1. A grinding apparatus for grinding an end surface of a diamond substrate, the grinding apparatus comprising:
a holding unit configured to hold the diamond substrate;
a grinding unit including a grinding tool for grinding the end surface of the diamond substrate held by the holding unit; and
a grinding feed unit for grinding-feeding the grinding unit in a direction that brings the grinding unit closer to and away from the end surface of the diamond substrate held by the holding unit,
the grinding tool having a base and a grinding blade mounted on the base,
the grinding blade being made of iron and acting on the end surface of the diamond substrate to cause a reaction between the iron and carbon of diamond and generate a compound containing austenite, thereby grinding the end surface of the diamond substrate.

2. The grinding apparatus of claim 1, wherein the iron is pure iron.

3. A grinding method for grinding an end surface of a diamond substrate, the grinding method comprising:
holding the diamond substrate by a holding unit; and
grinding the end surface of the diamond substrate held by the holding unit with a grinding unit including a grinding tool,
the grinding tool including a base and a grinding blade mounted on the base,
the grinding blade being made of iron and acting on the end surface of the diamond substrate to cause a reaction between the iron and carbon of diamond and generate a compound containing austenite, thereby grinding the end surface of the diamond substrate.

4. The grinding method of claim 3, wherein the iron is pure iron.

5. The grinding apparatus of claim 1, wherein
the diamond substrate is generated from a diamond ingot having a crystal plane (001) as an end surface,
a focal point of a laser beam having a wavelength transparent to the diamond is positioned at a depth equivalent to a thickness of the diamond substrate to be generated from the end surface of the diamond ingot,
the laser beam is applied to the diamond ingot, while the diamond ingot and the focal point are moved relative to each other in a [110] direction perpendicular to the crystal plane (110), to form a peel-off band,
the diamond ingot and the focal point are index-fed relative to each other in a direction parallel to the crystal plane (001) and perpendicular to the [110] direction,
the formation of the peel-off band and the index-feeding are repeated to form a peel-off layer parallel to the crystal plane (001) inside the diamond ingot, and
a peel-off surface of the diamond substrate peeled from the diamond ingot by using the peel-off layer as an interface is ground.

6. The grinding method of claim 3, wherein
the diamond substrate is generated from a diamond ingot having a crystal plane (001) as an end surface,
a focal point of a laser beam having a wavelength transparent to the diamond is positioned at a depth equivalent to a thickness of the diamond substrate to be generated from the end surface of the diamond ingot,
the laser beam is applied to the diamond ingot, while the diamond ingot and the focal point are moved relative to each other in a [110] direction perpendicular to the crystal plane (110), to form a peel-off band,
the diamond ingot and the focal point are index-fed relative to each other in a direction parallel to the crystal plane (001) and perpendicular to the [110] direction,
the formation of the peel-off band and the index-feeding are repeated to form a peel-off layer parallel to the crystal plane (001) inside the diamond ingot, and
a peel-off surface of the diamond substrate peeled from the diamond ingot by using the peel-off layer as an interface is ground.

7. A diamond substrate generation method for generating a diamond substrate from a diamond ingot, the diamond substrate generation method comprising:
positioning a focal point of a laser beam having a wavelength transparent to diamond at a depth equivalent to a thickness of the diamond substrate to be generated from an end surface of the diamond ingot;
applying a laser beam to the diamond ingot, while moving the diamond ingot and the focal point relative to each other, to form a peel-off layer;
peeling the diamond substrate from the diamond ingot by using the peel-off layer as an interface; and
grinding a peel-off surface of the diamond substrate with a grinding blade made of iron.

8. The grinding apparatus of claim 2, wherein
the diamond substrate is generated from a diamond ingot having a crystal plane (001) as an end surface,
a focal point of a laser beam having a wavelength transparent to the diamond is positioned at a depth equivalent to a thickness of the diamond substrate to be generated from the end surface of the diamond ingot,
the laser beam is applied to the diamond ingot, while the diamond ingot and the focal point are moved relative to each other in a [110] direction perpendicular to the crystal plane (110), to form a peel-off band,
the diamond ingot and the focal point are index-fed relative to each other in a direction parallel to the crystal plane (001) and perpendicular to the [110] direction,
the formation of the peel-off band and the index-feeding are repeated to form a peel-off layer parallel to the crystal plane (001) inside the diamond ingot, and
a peel-off surface of the diamond substrate peeled from the diamond ingot by using the peel-off layer as an interface is ground.

9. The grinding method of claim 4, wherein
the diamond substrate is generated from a diamond ingot having a crystal plane (001) as an end surface,
a focal point of a laser beam having a wavelength transparent to the diamond is positioned at a depth equivalent to a thickness of the diamond substrate to be generated from the end surface of the diamond ingot,
the laser beam is applied to the diamond ingot, while the diamond ingot and the focal point are moved relative to each other in a [110] direction perpendicular to the crystal plane (110), to form a peel-off band,
the diamond ingot and the focal point are index-fed relative to each other in a direction parallel to the crystal plane (001) and perpendicular to the [110] direction,
the formation of the peel-off band and the index-feeding are repeated to form a peel-off layer parallel to the crystal plane (001) inside the diamond ingot, and
a peel-off surface of the diamond substrate peeled from the diamond ingot by using the peel-off layer as an interface is ground.
